(19) United States
(12) Patent Application Publication
(10) Pub. No.: US 2026/0018773 A1
(43) Pub. Date: Jan. 15, 2026

(54) ASYMMETRIC TRANSMISSION LINE POWER COMBINERS

(71) Applicant: Texas Instruments Incorporated, Dallas, TX (US)

(72) Inventors: Arnab Das, Bangalore (IN); Krishnanshu Dandu, Dallas, TX (US)

(21) Appl. No.: 19/038,359

(22) Filed: Jan. 27, 2025

(30) Foreign Application Priority Data
Jul. 10, 2024 (IN) 202441052853

(51) Int. Cl. H01P 5/12

(52) U.S. Cl. CPC H01P 5/12

(57) ABSTRACT

An example device described herein includes a first pad, a second pad, and a transmission line including a first end configured to couple to monitor circuitry, wherein the transmission line includes a second end. The example device also includes a first switch coupled to the first pad, wherein the first switch is coupled to the transmission line between the first end and the second end. The example device further includes a second switch coupled to the second pad and to the second end of the transmission line, wherein an impedance of the first switch is higher than an impedance of the second switch.

### CROSS-REFERENCE TO RELATED APPLICATION

This patent application claims the benefit of and priority to Indian Provisional Patent Application No. 202441052853, filed Jul. 10, 2024, which Application is hereby incorporated herein by reference in its entirety.

This patent application also incorporates by reference the commonly assigned U.S. patent application Ser. No. 18/813,868, titled “Integration of Directional Couplers with Power Combiners,” filed Aug. 23, 2024.

### TECHNICAL FIELD

This description relates generally to power combiners and, more particularly, to asymmetric transmission line power combiners.

### BACKGROUND

A millimeter wave (mmWave) radar sensor may include a multiple-input multiple-output (MIMO) transceiver with an internal loopback system to support calibration, monitoring and/or functional safety requirements. The loopback system connects the multiple transmit power outputs of the MIMO transceiver to the receiver of the MIMO transceiver. Such a loopback system enables attenuated versions of the output signals generated at the transmit power outputs to be fed back to the receiver. The receiver receives these feedback signals and provides them to one or more circuits for various purposes. For example, a monitor circuit coupled to or otherwise included in the receiver can use the feedback signals to check the functionality of individual transmitter power outputs in operation and measure characteristics such as average power output, peak power output, gain mismatch between power outputs, phase mismatch between power outputs, etc., to ensure reliable transmitter performance. Some such loopback systems utilize a transmission line power combiner that couples the multiple transmit power outputs of the MIMO transceiver collectively to a transmission line that combines the power from the multiple transmit power outputs and feeds it back to the receiver of the MIMO transceiver. In some examples, the feedback signals can be used for producing a local oscillator signal in the receiver.

### SUMMARY

For methods and apparatus to implement asymmetric transmission line power combiners, an example device described herein includes a first pad, a second pad, and a transmission line including a first end configured to couple to monitor circuitry, wherein the transmission line includes a second end. The example device also includes a first switch coupled to the first pad, wherein the first switch is coupled to the transmission line between the first end and the second end. The example device further includes a second switch coupled to the second pad and to the second end of the transmission line, wherein an impedance of the first switch is higher than an impedance of the second switch.

For methods and apparatus to implement asymmetric transmission line power combiners, another example device described herein includes a transmission line having a first end and a second end, the first end to couple to circuitry to monitor a plurality of transmit power outputs of the device. The example device also includes switches to couple the transmit power outputs with the transmission line, a first switch of the switches to couple a first transmit power output of the transmit power outputs to the transmission line between the first end and the second end of the transmission line, a second switch of the switches to couple a second transmit power output of the transmit power outputs to the second end of the transmission line, and the second switch having a lower impedance than the first switch.

For methods and apparatus to implement asymmetric transmission line power combiners, an example non-transitory computer-readable medium described herein includes computer-readable instructions to cause at least one processor circuit to at least cause a plurality of transmit power outputs of a device to activate sequentially for respective time intervals in a monitoring period, the transmit power outputs in communication respectively with a plurality of switches coupled to a transmission line at respective positions spaced along the transmission line, the transmission line having a termination and an output, the output coupled to circuitry to monitor the transmit power outputs. Also, for a first one of the time intervals in which a first one of the transmit power outputs is active and other ones of the transmit power outputs are inactive, the computer-readable instructions also cause one or more of the at least one processor circuit to (i) cause a first one of the switches in communication with the first one of the transmit power outputs to deactivate, the first one of the switches coupled to the transmission line at a first one of the positions, and (ii) cause a second one of the switches coupled to the transmission line at a second one of the positions between the first one of the positions and the termination of the transmission line to activate.

### BRIEF DESCRIPTION OF THE DRAWINGS

FIG. 1 is a block diagram of an example device including an example transmission line power combiner.

FIG. 2 illustrates a first example implementation of the transmission line power combiner of FIG. 1.

FIG. 3 illustrates a second example implementation of the transmission line power combiner of FIG. 1.

FIG. 4 illustrates a third example implementation of the transmission line power combiner of FIG. 1.

FIG. 5 illustrates example performance results for the third example implementation of the transmission line power combiner illustrated in FIG. 4.

FIG. 6 illustrates a fourth example implementation of the transmission line power combiner of FIG. 1 that corresponds to an example low-area, loss-equalized asymmetric transmission line power combiner as described herein.

FIG. 7 illustrates example operation of the asymmetric transmission line power combiner of FIG. 6.

FIG. 8 illustrates an example equivalent circuit to model impedance in the asymmetric transmission line power combiner of FIG. 6.

FIG. 9 illustrates example performance results for the asymmetric transmission line power combiner of FIG. 6.

FIGS. 10-11 illustrate example performance results for alternative switch configurations used in the asymmetric transmission line power combiner of FIG. 6.

FIG. 12 illustrates an example use of the equivalent circuit of FIG. 8 to model impedance of a transmission line included in the asymmetric transmission line power combiner of FIG. 6.

FIG. 13 is a flowchart representative of example machine-readable instructions or example operations that may be at least one of executed, instantiated, or performed using an example programmable circuitry implementation of the device of FIG. 1 including the asymmetric transmission line power combiner of FIG. 6.

FIG. 14 is a block diagram of an example processing platform including programmable circuitry structured to execute, instantiate, or perform the example machine-readable instructions or perform the example operations of FIG. 13 to implement the device of FIG. 1 including the asymmetric transmission line power combiner of FIG. 6.

FIG. 15 is a block diagram of an example implementation of the programmable circuitry of FIG. 14.

FIG. 16 is a block diagram of another example implementation of the programmable circuitry of FIG. 14.

FIG. 17 is a block diagram of an example software/firmware/instructions distribution platform (e.g., one or more servers) to distribute software, instructions, or firmware (e.g., corresponding to the example machine-readable instructions of FIG. 13) to client devices associated with end users or consumers (e.g., for license, sale, or use), retailers (e.g., for sale, re-sale, license, or sub-license), or original equipment manufacturers (OEMs) (e.g., for inclusion in products to be distributed to, for example, retailers or to other end users such as direct buy customers).

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Example techniques to implement a low-area, loss-equalized asymmetric transmission line power combiner are described herein. As mentioned above, some MIMO transceivers include a loopback system that utilizes a transmission line power combiner that couples the multiple transmit power outputs of a MIMO transceiver collectively to a transmission line. The transmission line combines the power from the multiple transmit power outputs and feeds it back to the receiver of the MIMO transceiver. Such transmission line power combiners may utilize a symmetric design such that the loopback paths for the different transmit power outputs have similar lengths, which results in the different transmit power outputs experiencing similar attenuations. Symmetric transmission line power combiners can work well for relatively low numbers of transmit power outputs (e.g., two to four transmitters). However, for MIMO transceivers with a greater number of transmit power outputs (e.g., an eight-transmitter or sixteen-transmitters), such as those used in modern radar devices, a symmetric combiner may occupy a relatively large die area due to the relatively large size of the transmission line. Furthermore, such a MIMO transceiver may experience a relatively high attenuation loss due to the relatively large size of the transmission line and, thus, require extra amplifier stages to compensate for the extra loss, resulting in increased power consumption.

Transmission line power combiners that utilize an asymmetric design can reduce the die area of the combiner substantially relative to symmetric transmission line implementations. However, some asymmetric transmission line power combiners exhibit substantial attenuation loss disparities across the different transmit power outputs. In contrast, example asymmetric transmission line power combiners described herein equalize the attenuation loss among the multiple transmit power outputs and, thus, provide lower attenuation disparities relative to other asymmetric transmission line power combiners. Furthermore, example asymmetric transmission line power combiners described herein reduce the overall attenuation loss relative to other symmetric transmission line power combiner implementations, thereby reducing the number of amplifiers used to amplify the feedback signal and the associated current consumption relative to those symmetric transmission line power combiners. For example, an asymmetric transmission line power combiner described herein may exhibit 7-9 dB lower overall attenuation loss relative to a symmetric transmission line power combiner and, thus, save 20-40 milliamperes of current consumption. Furthermore, asymmetric transmission line power combiners described herein have substantially reduced die area (e.g., by at least a factor of four) relative to other symmetric transmission line power combiners because the overall length of the transmission lines described herein is shorter.

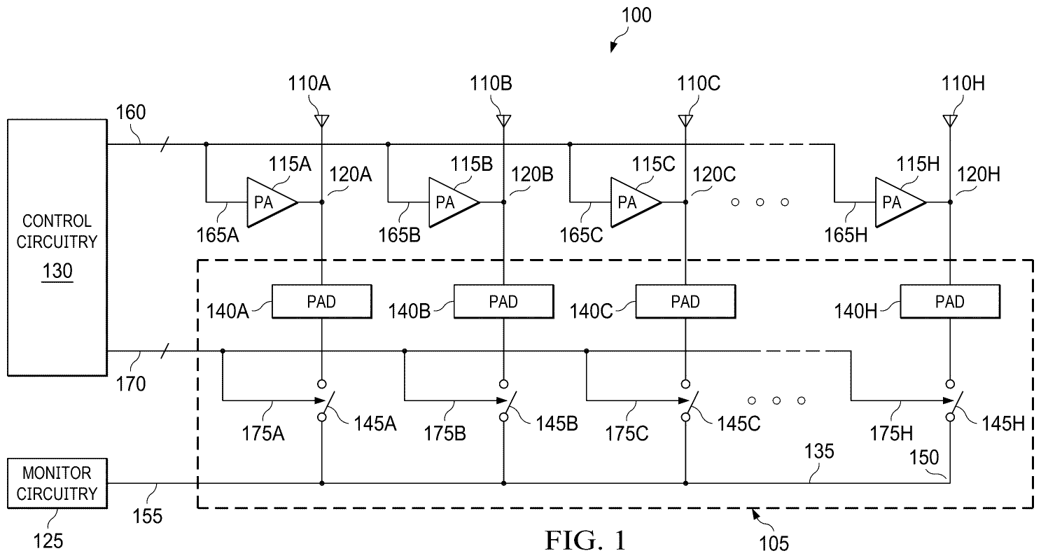

Turning to the figures, FIG. 1 is a block diagram of an example device 100 including an example transmission line power combiner 105. In the illustrated example of FIG. 1, the device 100 can implement at least a portion of a MIMO transceiver of an mm Wave radar sensor used in automotive applications, industrial applications, imaging radar, building automation, consumer electronics, etc. For example, the device 100 can be used to implement a front radar for an automobile, a corner radar for an automobile, etc., used in an advanced driver assistance system (ADAS). However, in other examples, the device 100 can correspond to any device that includes multiple transmitters. For example, the device 100 can correspond to a mobile communication device having multiple transmit antennas (e.g., an antenna array), an industrial detection and imaging radar, etc. Although combiner 105 is described herein as a combiner in a transmitter system, the same techniques may be implemented in a splitter circuit.

As such, the device 100 includes multiple example antennas 110A-H and corresponding example power amplifiers (PAs) 115A-H to produce multiple transmit signals to be output by the device 100. The antennas 110A-H can be implemented with any appropriate technology and can be external antennas, internal antennas, etc., or any combination thereof. The antennas 110A-H are coupled to respective example transmit power outputs 120A-H of the PAs 115A-H. The PAs 115A-H can be implemented with any appropriate amplifier technology to generate output signals at the transmit power outputs 120A-H, which drive the respective antennas 110A-H to produce the transmit signals to be output by the device 100. In some examples, the antennas 110A-110H may be integrated into the device 100, while in other example the antennas 110A-110H may be external to the device 100.

In the illustrated example of FIG. 1, the device includes an example loopback system implemented by the transmission line power combiner 105, example monitor circuitry 125 and example control circuitry 130. In some examples, the monitor circuitry 125 and/or the control circuitry 130 of FIG. 1 may be instantiated (e.g., creating an instance of, bring into being for any length of time, materialize, implement, etc.) by programmable circuitry such as a Central Processor Unit (CPU) executing first instructions. Also or alternatively, the monitor circuitry 125 and/or the control circuitry 130 of FIG. 1 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the monitor circuitry 125 and/or the control circuitry 130 of FIG. 1 may, thus, be instantiated at the same or different times. Some or all of the monitor circuitry 125 and/or the control circuitry 130 of FIG. 1 may be instantiated, for example, in one or more threads executing concurrently on hardware or in series on hardware. Moreover, in some examples, some or all of the monitor circuitry 125 and/or the control circuitry 130 of FIG. 1 may be implemented by microprocessor circuitry executing instructions or FPGA circuitry performing operations to implement one or more virtual machines or containers.

In the illustrated example, the transmission line power combiner 105 of the device 100 includes an example transmission line 135, example pads 140A-H and example switches 145A-H. The transmission line power combiner 105 uses the pads 140A-H and the switches 145A-H to couple the transmit power outputs 120A-H of the PAs 115A-H to the transmission line 135. The transmission line 135 of the illustrated example has an example termination end 150 and an example output end 155. In the illustrated example, the output end 155 of the transmission line 135 is coupled to the monitor circuitry 125.

In the illustrated example, the transmission line power combiner 105 combines the power from the transmit power outputs 120A-H of the PAs 115A-H and feeds the combined power back to the monitor circuit 125. The monitor circuit 125 processes the feedback signal provided at the output end 155 of the transmission line to check the functionality of individual transmitter transmit power outputs 120A-H in operation and measure characteristics such as average power output, peak power output, gain mismatch between the transmit power outputs 120A-H, phase mismatch between the transmit power outputs 120A-H, etc. In some examples, the monitor circuit 125 uses the measured characteristics to ensure reliable transmitter performance, identify fault(s), implement safe operation mode(s), etc.

To facilitate monitoring of the transmit power outputs 120A-H individually, the control circuitry 130 of the illustrated example defines monitoring periods that are triggered or otherwise activated, enabled, etc., intermittently (e.g., periodically, aperiodically, etc.) during operation of the device 100. For example, a monitoring period may have a duration of 10 milliseconds (ms), or some other duration, and be triggered at periodic intervals of 10 seconds (sec), or some other periodic interval. The control circuitry 130 further defines multiple time intervals within the monitoring period and assigns the time intervals respectively to the transmit power outputs 120A-H. Thus, in some examples, the number of time intervals in a monitoring period equals the number of transmit power outputs 120A-H. For example, if there are eight (8) transmit power outputs 120A-H, then the control circuitry 130 may define eight (8) time intervals within a given monitoring period.

In the illustrated example, the control circuitry 130 causes the transmit power outputs 120A-H of the PAs 115A-H to activate sequentially for respective time intervals in a monitoring period. For example, in a first time interval of a monitoring period, the control circuitry 130 may cause the transmit power output 120A of the PA 115A to be active and the other transmit power output 120B-H of the PAs 115B-H to be inactive. Then, in a second interval of the monitoring period, the control circuitry 130 may cause the transmit power output 120B of the PA 115B to be active and the other transmit power output 120A,C-H of the PAs 115A,C—H to be inactive. In this example, the control circuitry 130 continues performing similar operations until the last time interval of the monitoring period during which the control circuitry 130 causes the transmit power output 120H of the PA 115H to be active and the other transmit power output 120A-C of the PAs 115A-C to be inactive. In some examples, during normal operation outside of a monitoring period, the control circuitry 130 controls or otherwise cause one or more or all of the transmit power outputs 120A-H of the PAs 115A-H to activate.

To facilitate control of the PAs 115A-H as described above, the control circuitry 130 of the illustrated example includes example transmit control outputs 160 that are coupled to respective control inputs 165A-H of the PAs 115A-H. In the illustrated example, the control circuitry 130 uses the transmit control outputs 160 to selectively set the control inputs 165A-H of the PAs 115A-H to individually activate (or enable, turn on, etc.) or deactivate (or disable, turn off, etc.) the PAs 115A-H and, thus, the transmit power outputs 120A-H of the PAs 115A-H. For example, the PAs 115A-H may be configured such that a first logic value (e.g., a logic-1 value, a logic-0 value, a logic HIGH value, a logic LOW value, etc.) applied to the control input 165A-H of a given PA 115A-H causes that PA's transmit power output 120A-H to activate (or enable, turn on, etc.), whereas a different second logic value (e.g., a logic-0 value, a logic-1 value, a logic LOW value, a logic HIGH value, etc.) applied to the control input 165A-H of that given PA 115A-H causes PA's transmit power output 120A-H to deactivate (or disable, turn off, etc.). In some examples, the transmit control outputs 160 of the control circuitry 130 are implemented by one or more pins, lines, traces, buses, etc.

In the illustrated example, the control circuitry 130 also includes example switch control outputs 170 that are coupled to respective control inputs 175A-H of the switches 145A-H. The control circuitry 130 uses the switch control outputs 170 to selectively set the control inputs 175A-H of the switches 145A-H to individually couple (or connect, etc.) or decouple (or disconnect, etc.) the respective pads 140A-H and, thus, the respective transmit power outputs 120A-H, to the transmission line 135. For example, the switches 145A-H may be configured such that a first logic value (e.g., a logic-1 value, a logic-0 value, a logic HIGH value, a logic LOW value, etc.) applied to the control input 175A-H of a given switch 145A-H causes that switch to activate (or enable, close, etc.), whereas a different second logic value (e.g., a logic-0 value, a logic-1 value, a logic LOW value, a logic HIGH value, etc.) applied to the control input 175A-H of that given switch 145A-H causes the switch to deactivate (or disable, open, etc.). In some examples, the switch control outputs 170 of the control circuitry 130 are implemented by one or more pins, lines, traces, buses, etc. In some examples, during normal operation outside of a monitoring period, the control circuitry 130 controls or otherwise causes one or more or all of the switches 145A-H to activate (or enable, close, etc.) or otherwise decouple (e.g., disconnect) their respective transmit power outputs 120A-H from the transmission line 135. Further details concerning how the control circuitry 130 operates to selectively control the switches 145A-H during a monitoring period is provided below.

In the illustrated example, the pads 140A-H couple the transmit power outputs 120A-H of the PAs 115A-H to the antennas 110A-H and the switches 145A-H of the transmission line power combiner 105. The pads 140A-H can be implemented by any conductive material, structure, etc., in any appropriate arrangement. In some examples, the pads 140A-H are implemented by ground-signal-ground (GSG) pads. In some examples, such as examples in which the antennas 110A-H are internal to the device 100, the pads 140A-H are omitted as the transmit power outputs 120A-H of the PAs 115A-H can be coupled internally to the antennas 110A-H and the switches 145A-H of the transmission line power combiner 105.

In the illustrated example, the switches 145A-H can be implemented by any type of switch technology. In some examples, the switches 145A-H can be implemented by one or more example transistor switches 145A-H. For example, the transistor switches 145A-H may be n-channel metal-oxide semiconductor field-effect transistors (MOSFETs). In some examples, one or more of the transistor switches 145A-H may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices, or any combinations thereof. In some examples, one or more of the transistor switches 145A-H may be p-channel MOSFETs. In some examples, one or more of the transistor switches 145A-H may be p-channel FETs, p-channel IGBTs, p-channel JFETs, PNP BJTs, or, with slight modifications, N-type equivalent devices, or any combination thereof. In some examples, one or more of the transistor switches 145A-H may be depletion mode devices, drain-extended devices, enhancement mode devices, natural transistors or other type of device structure transistors. In some examples, one or more of the transistor switches 145A-H may be implemented in/over a silicon substrate (Si), a silicon carbide substrate (SiC), a gallium nitride substrate (GaN) or a gallium arsenide substrate (GaAs). In some examples, the switches 145A-H are shunt switches.

In examples in which the switches 145A-H are transistor switches 145A-H, the impedance of a given transistor switch 145A-H is proportional to its channel length (also referred to as the length of the transistor switch) and inversely proportional to its channel width also referred to as the width of the transistor switch). Also, in some examples, the widths of the transistor switches 145A-H are limited to a set of available widths. For example, the transistor switches 145A-H may have widths limited to a set of available widths including 16 micrometers (μm), 32 μm, 50 μm, etc. In some examples, the widths of the transistor switches 145A-H are the same. However, in some examples, one or more of the transistor switches 145A-H may have widths that are different from the widths of others of the transistor switches 145A-H.

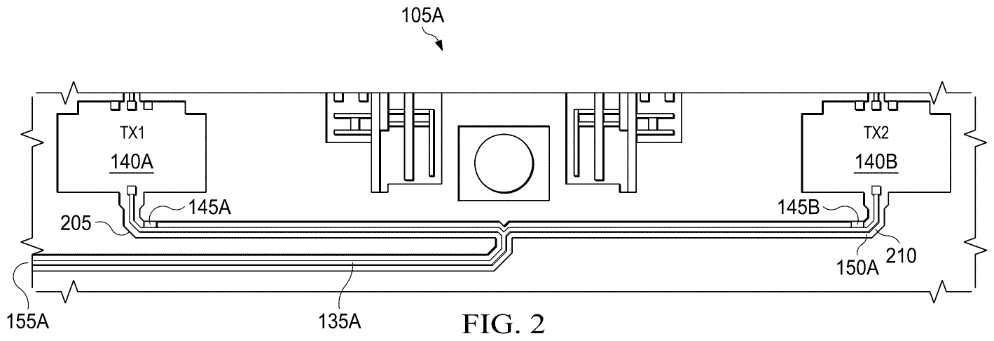

FIG. 2 illustrates a first example implementation 105A of the transmission line power combiner 105 of FIG. 1. The example transmission line power combiner 105A of FIG. 2 supports two (2) transmitters and, thus, includes two (2) pads 140A-B and two (2) switches 145A-B described above. The transmission line power combiner 105A also includes a first example implementation 135A of the transmission line 135 included in the transmission line power combiner 105 of FIG. 1. The example transmission line 135A of FIG. 2 is an example of a symmetric transmission line 135A and, thus, the transmission line power combiner 105A is an example of a symmetric transmission line power combiner 105A.

In the illustrated example, the pad 140A/switch 145A combination associated with the first transmitter is coupled to a first position 205 on the transmission line 135A (labeled “TX1” in FIG. 2) and the pad 140B/switch 145B combination associated with the second transmitter is coupled to a second position 210 on the transmission line 135A (labeled “TX2” in FIG. 2). Furthermore, the second position 210 (TX2) corresponds to the termination end 150A of the transmission line 135A. As illustrated in FIG. 2, the transmission line 135A is structured such that the feedback path from the first position 205 associated with the first transmitter (TX1) to the output 155A of the transmission line 135A and the feedback path from the second position 210 associated with the second transmitter (TX2) to the output 155A of the transmission line 135A have the same length or substantially similar lengths. Such a structure results in the feedback signals associated with the first and second transmitters experiencing the same or substantially similar attenuation, thereby yielding little to no mismatch between the two feedback signals. Thus, the monitor circuitry 125 can apply the same amplification factor to both of the feedback signals and, thus, utilize the same number of amplifier(s) for both feedback paths.

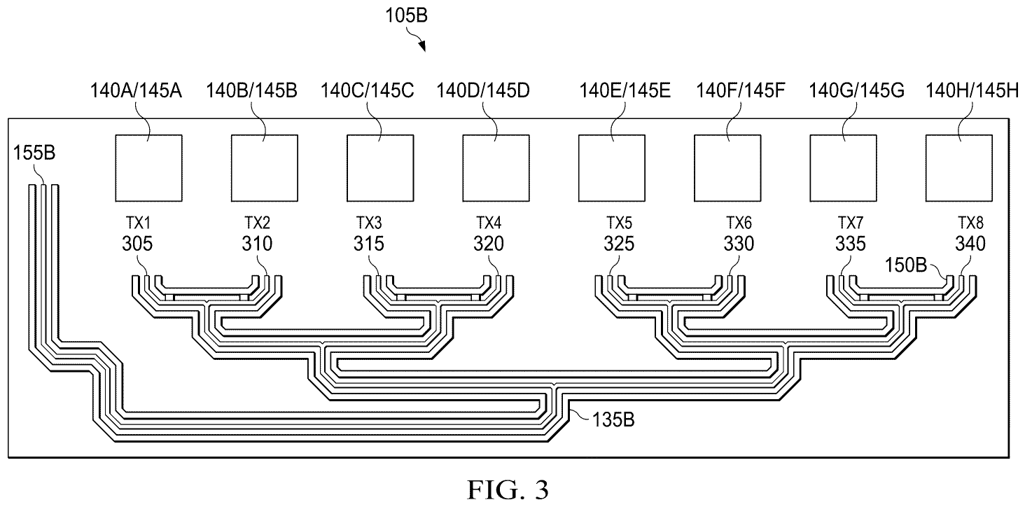

FIG. 3 illustrates a second example implementation 105B of the transmission line power combiner 105 of FIG. 1. The example transmission line power combiner 105B of FIG. 3 supports eight (8) transmitters and, thus, includes eight (8) pads 140A-H and eight (8) switches 145A-H, as described above. The transmission line power combiner 105B also includes a second example implementation 135B of the transmission line 135 included in the transmission line power combiner 105 of FIG. 1. The example transmission line 135B of FIG. 3 is another example of a symmetric transmission line 135B and, thus, the transmission line power combiner 105B is another example of a symmetric transmission line power combiner 105B. Furthermore, relative to the transmission line 135A of FIG. 2, the transmission line 135B of FIG. 3 shows potential drawbacks with using symmetric transmission lines in power combiners.

In the illustrated example of FIG. 3, the pad 140A/switch 145A combination associated with the first transmitter is coupled to a first position 305 on the transmission line 135B (labeled “TX1” in FIG. 3), the pad 140B/switch 145B combination associated with the second transmitter is coupled to a second position 310 on the transmission line 135B (labeled “TX2” in FIG. 3), and so on, with the pad 140H/switch 145H combination associated with the eighth transmitter coupled to an eighth position 340 on the transmission line 135B (labeled “TX8” in FIG. 3). Furthermore, the eighth position 340 (TX8) corresponds to the termination end 150B of the transmission line 135B. As illustrated in FIG. 3, the transmission line 135B is structured such that the feedback paths from the different positions 305-340 associated with the first through eighth transmitters (TX1-TX8) to the output 155B of the transmission line 135B have the same length or substantially similar lengths. Such a structure results in the feedback signals associated with the first through eighth transmitters experiencing the same or substantially similar attenuation, thereby yielding little to no mismatch between the eight feedback signals. Thus, the monitor circuitry 125 can apply the same amplification factor to the different feedback signals.

However, as illustrated in FIG. 3, the transmission line 135B utilizes four (4) layers to implement its symmetric structure, as compared to two layers used by the transmission line 135A of FIG. 2. The increased number of layers is due to the increased number of transmitters coupled to the transmission line 135B. In some examples, a symmetric transmission line having a structure similar to the transmission line 135B will require a number of layers corresponding to half the number of transmitters to be coupled to the transmission line.

In some examples, the width of a layer of the transmission line 135B is 40 μm. Also, in some examples, the overall length of the transmission line 135B increases with the number of transmitters as the widths of the pads 140A-H (e.g., which may be GSG pads) set a minimum distance between adjacent transmitter connections. With these constraints, in some examples, the transmission line 135B occupies a die area of approximately 4 (layers)×40 μm (width)×4 mm (length)=0.64 square millimeters (mm²), which consumes substantial die space in at least some implementations. Furthermore, the overall length of the feedback paths of transmission line 135B yields an overall passive loss for the combiner 105B that can be approximately 29-32 decibels (dB) in some examples. Thus, in some such examples, the monitor circuitry 125 may require additional amplifiers and hence additional power dissipation to amplify the feedback signals to adequate levels for subsequent processing.

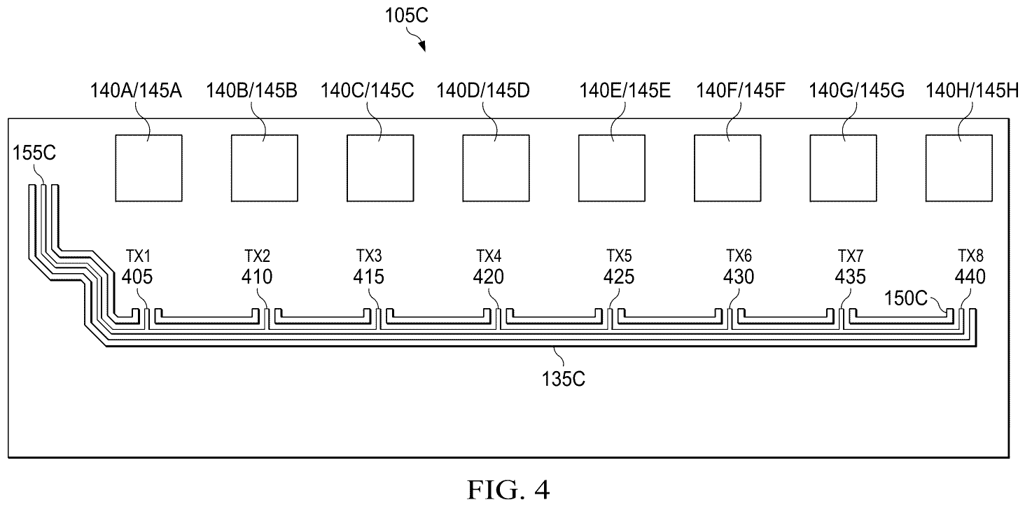

FIG. 4 illustrates a third example implementation 105C of the transmission line power combiner 105 of FIG. 1. The example transmission line power combiner 105C of FIG. 4 supports eight (8) transmitters and, thus, includes eight (8) pads 140A-H and eight (8) switches 145A-H, as described above. The transmission line power combiner 105C also includes a third example implementation 135C of the transmission line 135 included in the transmission line power combiner 105 of FIG. 1. The example transmission line 135C of FIG. 4 is an example of an asymmetric transmission line 135C and, thus, the transmission line power combiner 105B is an example of an asymmetric transmission line power combiner 105C.

In the illustrated example of FIG. 4, the pad 140A/switch 145A combination associated with the first transmitter is coupled to a first position 405 on the transmission line 135C (labeled “TX1” in FIG. 3), the pad 140B/switch 145B combination associated with the second transmitter is coupled to a second position 410 on the transmission line 135C (labeled “TX2” in FIG. 3), and so on, with the pad 140H/switch 145H combination associated with the eighth transmitter coupled to an eighth position 440 on the transmission line 135C (labeled “TX8” in FIG. 3). Furthermore, the eighth position 440 (TX8) corresponds to the termination end 150C of the transmission line 135C. As illustrated in FIG. 4, the asymmetric transmission line 135C is implemented with one layer and thus the width of the asymmetric transmission line 135C is reduced by a factor of four (4) relative to the symmetric transmission line 135B, although both support eight (8) transmitters. Thus, the asymmetric transmission line 135C occupies a die area of 40 μm (width)×4 mm (length)=0.16 mm², which is four times smaller than the area of the symmetric transmission line 135B.

However, as also illustrated in FIG. 4, the transmission line 135C is structured such that the feedback paths from the different positions 405-440 associated with the first through eighth transmitters (TX1-TX8) to the output 155C of the transmission line 135C have different lengths. For example, the feedback path from position 405 (TX1) to the output 155C of the transmission line 135C may cover approximately 10 μm, whereas the feedback path from position 440 (TX8) to the output 155C of the transmission line 135C may cover approximately 4 millimeters (mm). Such a structure results in the feedback signals associated with the first through eighth transmitters experiencing different attenuations, thereby yielding potentially substantial mismatches between the eight feedback signals.

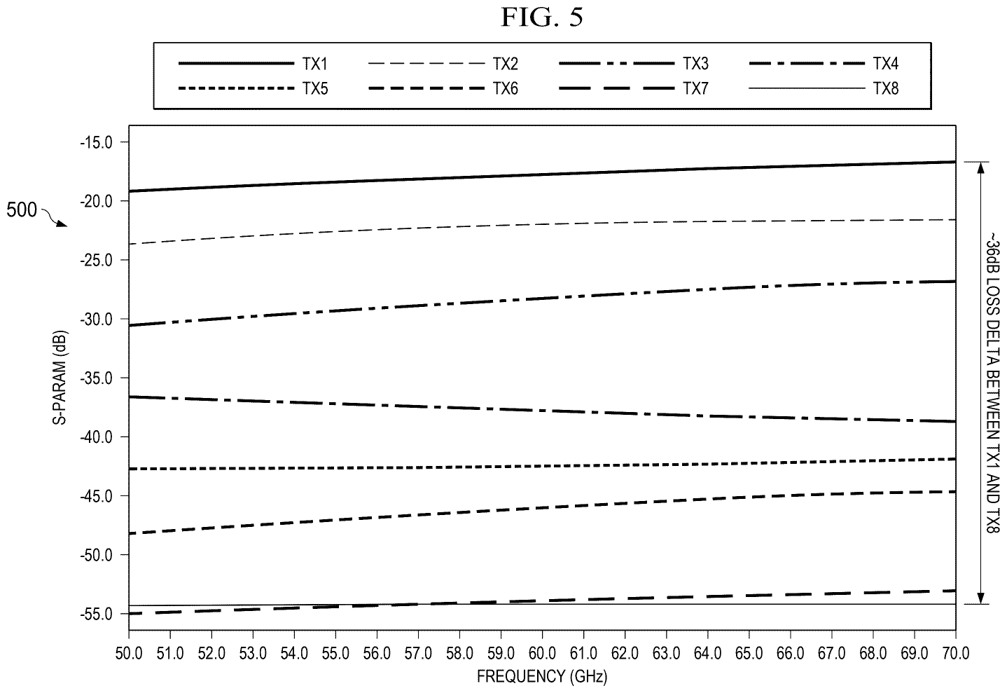

For example, FIG. 5 illustrates example performance results 500 for the asymmetric transmission line power combiner 105C illustrated in FIG. 4. The performance results 500 demonstrate that the differences in loss among the different feedback paths associated with the different transmittals can be substantial, such as approximately 36 dB in the illustrated example. In some examples, it may be difficult for the monitor circuitry 125 to compensate for such a large dynamic range of loss.

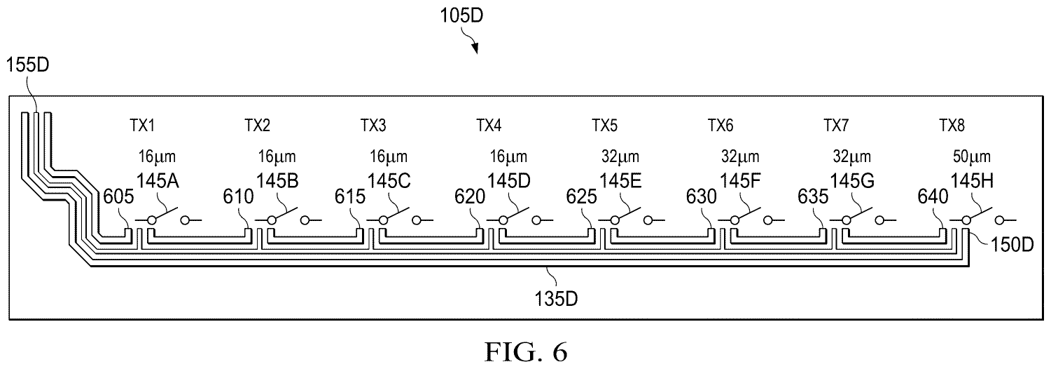

FIG. 6 illustrates a fourth example implementation 105D of the transmission line power combiner 105 of FIG. 1. The example transmission line power combiner 105D of FIG. 6 supports eight (8) transmitters and, thus, includes eight (8) switches 145A-H coupled to eight (8) pads 140A-H (not shown), as described above. The transmission line power combiner 105D also includes a fourth example implementation 135D of the transmission line 135 included in the transmission line power combiner 105 of FIG. 1. The example transmission line 135D of FIG. 6 is another example of an asymmetric transmission line 135D and, thus, the transmission line power combiner 105D is another example of an asymmetric transmission line power combiner 105D. However, in contrast with the asymmetric transmission line power combiner 105B of FIG. 4, the asymmetric transmission line power combiner 105D of FIG. 6 is a low-area, loss-equalized asymmetric transmission line power combiner.

In the illustrated example of FIG. 6, the switch 145A associated with the first transmitter is coupled to a first position 605 on the transmission line 135D (labeled “TX1” in FIG. 6), the switch 145B associated with the second transmitter is coupled to a second position 610 on the transmission line 135D (labeled “TX2” in FIG. 6), and so on, with the switch 145H associated with the eighth transmitter coupled to an eighth position 640 on the transmission line 135D (labeled “TX8” in FIG. 6). Furthermore, the eighth position 640 (TX8) corresponds to the termination end 150D of the transmission line 135D. As illustrated in FIG. 6, the asymmetric transmission line 135D is implemented with one layer and thus, like the asymmetric transmission line 135C of FIG. 4, the width of the asymmetric transmission line 135D is reduced by a factor of four (4) relative to the symmetric transmission line 135B, although both support eight (8) transmitters. In addition, the length of transmission line 135D from first position 605 to the output 155C may be substantially shorter than the length of transmission line 135B from first position 305 to the output 155B. Thus, like the asymmetric transmission line 135C of FIG. 4, the asymmetric transmission line 135D of FIG. 6 occupies a die area of 40 μm (width)×4 mm (length)=0.16 mm², which is four times smaller than the area of the symmetric transmission line 135B. The asymmetric transmission line 135D may use less metal than the symmetric transmission line 135B.

As also illustrated in FIG. 6, the transmission line 135D is structured such that the feedback paths from the different positions 605-640 associated with the first through eighth transmitters (TX1-TX8) to the output 155D of the transmission line 135D have different lengths. For example, the feedback path from position 605 (TX1) to the output 155D of the transmission line 135D may cover approximately 10 μm, whereas the feedback path from position 640 (TX8) to the output 155D of the transmission line 135D may cover approximately 4 mm. As described above, such a structure results in the different feedback paths associated with the first through eighth transmitters experiencing different passive losses along the transmission line 135D. However, relative to the asymmetric transmission line power combiner 105C of FIG. 4, the asymmetric transmission line power combiner 105D of FIG. 6 achieves a reduced overall attenuation/loss mismatch among the different feedback paths.

The asymmetric transmission line power combiner 105D of FIG. 6 achieves such an overall attenuation/loss mismatch reduction by using switches 140A-H with progressive width scaling from the output end 155D to the termination end 150D of the transmission line 135D, as shown in FIG. 6. Due to the inverse proportional relationship between switch width and impedance described above, such progressive width scaling results in the switches 140A-H coupled to the transmission line 135D having progressive impedance scaling from the output end 155D to the termination end 150D of the transmission line 135D. For example, in the asymmetric transmission line power combiner 105D of FIG. 6, the switches 140A-D (which are closest to the output end 155D of the transmission line 135D) have widths of 16 μm, the switches 140E-G (which are farther from the output end 155D of the transmission line 135D) have widths of 32 μm, and the switch 145H (which is farthest from the output end 155D of the transmission line 135D) has a width of 50 μm. As a result, the switches 140A-D (which are closest to the output end 155D of the transmission line 135D) have higher impedances than the switches 140E-H (which are farther from the output end 155D of the transmission line 135D), the switches 140E-G (which are farther from the output end 155D of the transmission line 135D than the switches 140A-C but closer than the switch 145H) have lower impedances than the switches 140A-C but higher impedances than the switch 145H, and the switch 145H (which is farthest from the output end 155D of the transmission line 135D) has a lower impedance than the switches 140A-G. For example, a switch having a width of 16 μm has an impedance of approximately 35 ohms, whereas a switch having a width of 50 μm has an impedance of approximately 10 ohms. Of course, in other examples, the switches 140A-H may have other widths and impedances. However, in such examples, the widths of the switches 140A-H are the same or increase in the direction from the output end 155D to the termination end 150D of the transmission line 135D, thereby causing the impedances of the switches 140A-H to be the same or increase (e.g., by at least twenty percent or some other amount(s)) in the direction from the output end 155D to the termination end 150D of the transmission line 135D. Also, in some examples, the lengths of the sections of the transmission line 135D between and two adjacent transmitter connection positions 605-640 may be designed to be roughly one-fourth of the lambda length of the transmission line (where the lambda length is approximately 1.4 mm in the illustrated example) to gain advantage from impedance inversion.

In some examples, a channel width of switch 145H is at least twice, three, or four times greater than the channel width of switch 145A (i.e., a ratio of at least 2, 3, or 4). As a result, an impedance of switch 145A is at least twice, three, or four times greater than the channel width of switch 145H. A channel width of switch 145E may be at least 1.5, 2.0, or 2.5 times greater than the channel width of switch 145A (i.e., a ratio of at least 1.5, 2.0, or 2.5). An impedance of switch 145A is at least 1.5, 2.0, or 2.5 times greater than the channel width of switch 145E. And a channel width of switch 145H may be at least 1.2, 1.5, or 2.0 times greater than the channel width of switch 145E (i.e., a ratio of at least 1.2, 1.5, or 2.0). An impedance of switch 145E is at least 1.2, 1.5, or 2.0 times greater than the channel width of switch 145H. In some examples, all of the switches 145A-145H have the same channel length. These dimensions and parameters are merely examples of how to implement the techniques of this disclosure.

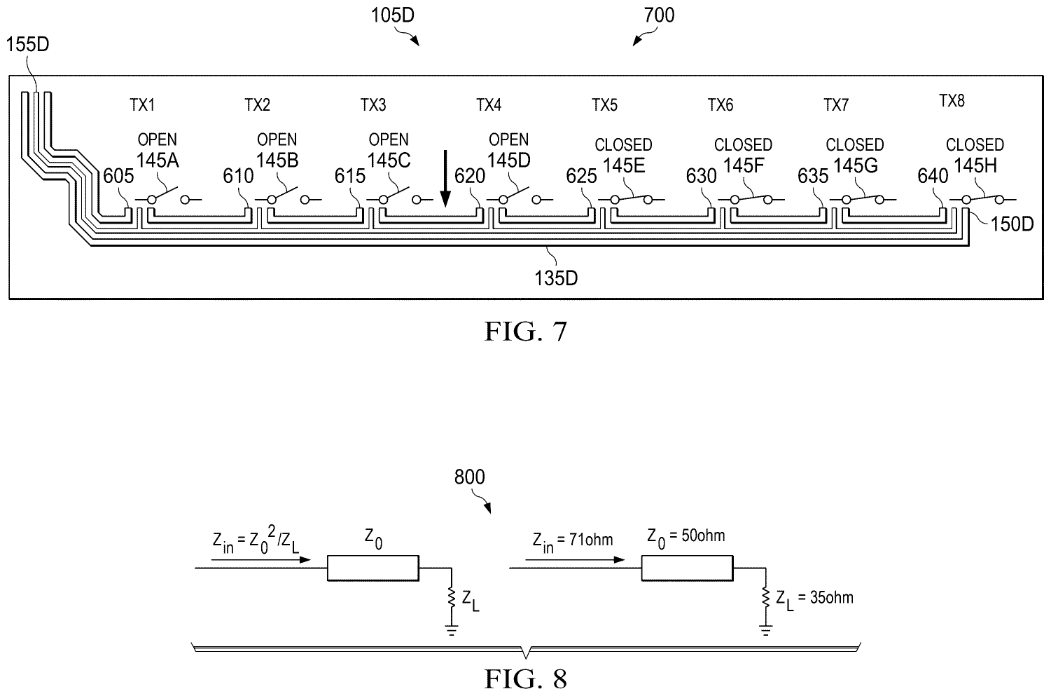

The asymmetric transmission line power combiner 105D of FIG. 6 also achieves its reduction in overall attenuation/loss mismatch through a novel operation of the switches 140A-H by the control circuitry 130. With reference to FIG. 1, the control circuitry 130 controls the switches 140A-H to couple different combinations of the transmit power outputs 120A-H to the transmission line 135D depending on which transmit power output 120A-H is active during a particular time interval of a monitoring period. An example operation 700 of the control circuitry 130 to control the switches 140A-H is illustrated in FIG. 7.

Again with reference to FIG. 1, for an eight (8) transmitter implementation of the device 100 corresponding to the transmission line 135D, there will be eight (8) transmit power outputs 120A-H of eight (8) PAs 115A-H coupled to the transmission line 135D at the positions 605-640 (e.g., TX1-8) via the eight (8) pads 140A-H and switches 145A-H. As described above, the control circuitry 130 will operate to cause the transmit power outputs 120A-H of the PAs 115A-H to activate sequentially for respective time intervals in a monitoring period. Furthermore, with reference to the example operation 700 of FIG. 7, during a given time interval in which a given one of the transmit power outputs 120A-H is active, the control circuitry 130 operates to cause the given switch 145A-H in communication with the active transmit power output 120A-H to couple that transmit power output 120A-H to the transmission line 135D. Also, the control circuitry 130 operates to cause any of the switches 145A-H coupled at positions 605-640 on the transmission line 135D between the output end 155D and the position of the switch 145A-H coupled to the active transmit power output 120A-H to couple their respective transmit power outputs 120A-H to the transmission line 135D. Furthermore, the control circuitry 130 operates to cause any of the switches 145A-H coupled at positions 605-640 on the transmission line 135D between the position of the switch 145A-H coupled to the active transmit power output 120A-H and the termination end 150D to decouple their respective transmit power outputs 120A-H from the transmission line 135D.

For example, if the switches 145A-H are shunt switches, during a given time interval in which a given one of the transmit power outputs 120A-H is active, the control circuitry 130 operates to cause the given switch 145A-H in communication with that transmit power output 120A-H to deactivate (e.g., open), which couples the active transmit power output 120A-H to the transmission line 135D. Also, the control circuitry 130 operates to cause any of the switches 145A-H coupled at positions 605-640 on the transmission line 135D between the output end 155D and the position of the switch 145A-H coupled to the active transmit power output 120A-H to deactivate (e.g., open). Furthermore, the control circuitry 130 operates to cause any of the switches 145A-H coupled at positions 605-640 on the transmission line 135D between the position of the switch 145A-H coupled to the active transmit power output 120A-H and the termination end 150D to activate (e.g., open), which decouples their respective transmit power outputs 120A-H from the transmission line 135D.

FIG. 7 illustrates such an operation 700 for the case in which the control circuitry 130 causes the transmit power output 120D corresponding to the switch 145D to be active during a time interval of a monitoring period. In this example, the control circuitry 130 causes the switch 145D to deactivate (e.g., open). The control circuitry 130 also causes the switches 145A-C, which are between the output end 155D of the transmission line 135D and the switch 145D, to deactivate (e.g., open). The control circuitry 130 further causes the switches 145E-H, which are between the switch 145D and the termination end 150D of the transmission line 135D, to activate (e.g., close). Stated more mathematically, when TX<n> (the n^{th} transmitter) is looping back (e.g., TX4 is looping back in FIG. 7), the TX<1:n−1>shunt switches are deactivated (e.g., open) and the TX<n:8>shunt switches are activated (e.g., closed). Such operation enables the given transmitter than is looping back to experience relatively low impedance in the direction towards the output end 155D of the transmission line 135D, and relatively high impedance in the direction towards the termination end 150D of the transmission line 135D, which causes the feedback signal to flow towards the output end 155D. Such operation also improves inter-transmitter isolation through the loopback path when a given transmitter is active.

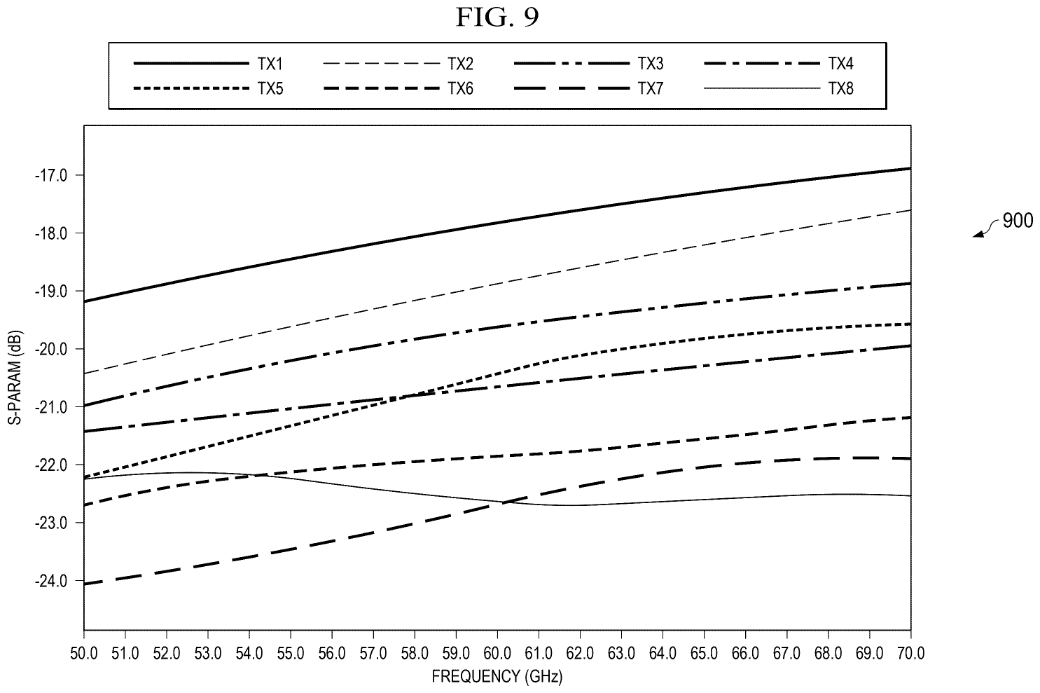

FIG. 8 illustrates an example equivalent circuit 800 to model impedance in the asymmetric transmission line power combiner 105D of FIG. 6. The equivalent circuit 800 models the impedance at a particular switch coupling position 605-640 in the direction towards the termination end 150D of the transmission line 135D. In the equivalent circuit 800, the impedance of the transmission line 135D is represented by the variable Z₀ and the impedance of the switch 145A-H at the particular switch coupling position 605-640 is represented by the variable Z_{L}. As shown in FIG. 8, using the equivalent circuit 800, the impedance at the particular switch coupling position 605-640 in the direction towards the termination end 150D of the transmission line 135D is given by Equation 1:

$${Z}_{i n} = \frac{{Z}_{0}^{2}}{{Z}_{L}} \qquad Equation 1$$

FIG. 8 also illustrates evaluation of the equivalent circuit 800 for the example operation 700 of FIG. 7. In the operation 700, the impedance of the transmission line 135D is 50 ohms and the impedance of the switch 145D is 35 ohms. Thus, according to Equation 1, the impedance at the switch coupling position 620 (corresponding to the switch 145D) in the direction towards the termination end 150D of the transmission line 135D is 71 ohms. Furthermore, the impedance towards the output end 155D of the transmission line 135D is the line impedance of 50 ohms, which achieves a lower impedance towards the output end 155D than towards the termination end 150D.

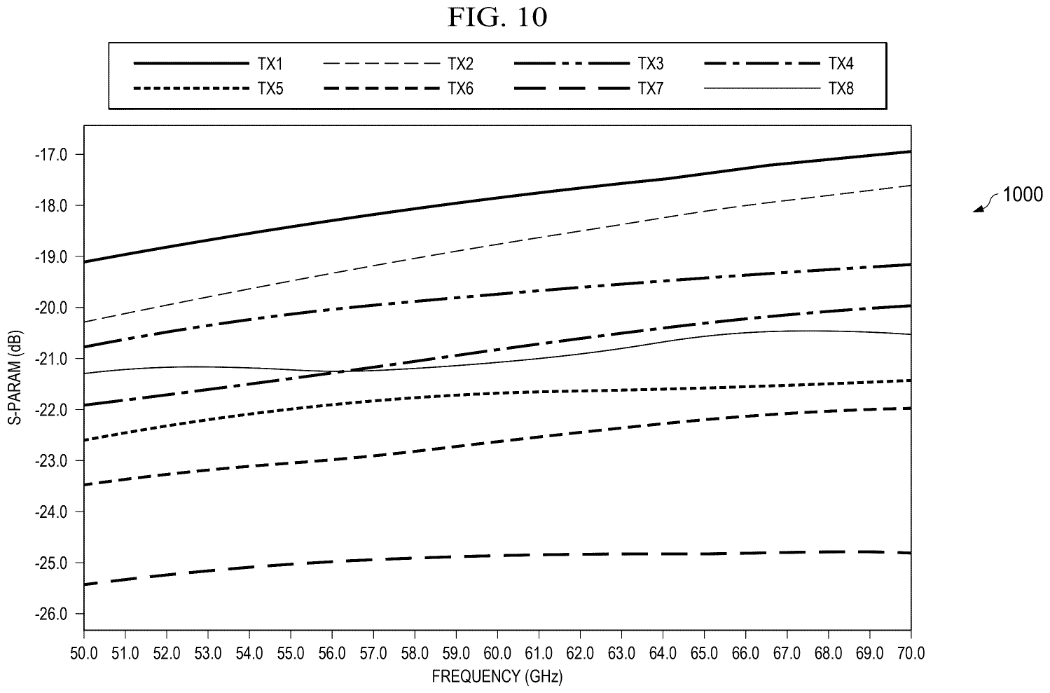

FIG. 9 illustrates example performance results 900 for the asymmetric transmission line power combiner 105D illustrated in FIG. 6. The performance results 900 depict loss versus frequency profiles for the different feedback paths from the positions 605-640 associated with the eight transmitters (TX1-TX8) to the output 155B of the transmission line 135B. The results 900 show that the differences in loss among the different feedback paths for the asymmetric transmission line power combiner 105D is approximately 5 dB, which is substantially less than the approximately 36 dB of loss exhibited by the other asymmetric transmission line power combiner 105C illustrated in FIG. 4. In some examples, such as small dynamic range of loss can be handled by one amplifier in the monitor circuitry 125. Also, in this example, the absolute feedback path loss for the asymmetric transmission line power combiner 105D is 7-9 dB lower than loss for the symmetric transmission line power combiner 105B described above. In some examples, the advantages of the asymmetric transmission line power combiner 105D are even more pronounced for a higher number of transmitters, such as sixteen transmitters, such as in imaging radar.

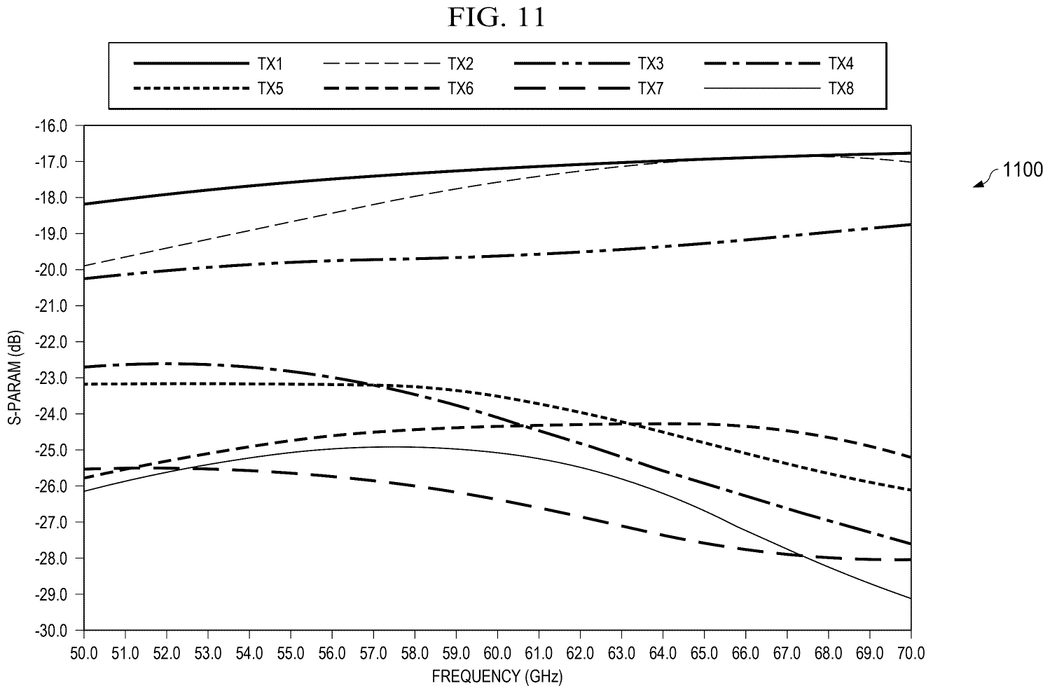

FIGS. 10-11 illustrate example performance results for alternative switch configurations used in the asymmetric transmission line power combiner 105D of FIG. 6. FIG. 10 illustrates example performance results 1000 for an example implementation in which all of the switches 145A-H have widths of 16 μm. FIG. 11 illustrates example performance results 1100 for an example implementation in which all of the switches 145A-H have widths of 50 μm. The performance results 1000 and 1100 demonstrate that using switches 145A-H having the same widths yields higher differences in loss among the different feedback paths than for the asymmetric transmission line power combiner 105D having progressive scaling of switch widths.

For example, the performance results 1000 show that when the switches 145A-H have widths of 16 μm, TX7 shows ˜2-2.7 dB higher loss than rest of the transmitters. This is because TX7 sees 50 ohms towards the output end 155D and 71 ohms towards the termination end 150D, which is nearly equal power split. A higher width switch can provide lower “on” resistance (e.g., a 50 μm switch gives an “on” resistance of 10 ohms Ron, and a 250 ohm post impedance inversion). The performance results 1100 show that when the switches 145A-H have widths of 50 μm, from TX4 onwards, there is approximately 4 dB higher loss than for the first three transmitters TX1-TX3. This is because a 50 μm switch has higher capacitance than a 16 μm switch and this capacitance shunts the signal from the transmission line 135D. The feedback signals from the farther transmitters TX4-8 transit more switches and thus experience more attenuation than feedback signals from the closer transmitters TX1-3.

Progressive scaling of switch size can solve the foregoing issues. The transmitters closer to the output end 155D of the transmission line 135D experience high impedance towards the termination end 150D and, thus, do not need a large size switch. However, transmitters farther from the output end 155D benefit from a larger switch size. In the illustrated example, transmitter TX7 experiences the worst signal split and a 50 μm switch at the TX8 position addresses this issue. The signals from the transmitters farther from the output end 155D experience less attenuation while travelling to the output end 155D due to the capacitances of the 16 μm shunt switches associated with transmitters TX1-4. This scheme provides a low loss for all the transmitters and strives to equalize their loss despite their signals travelling approximately four millimeter different signal paths.

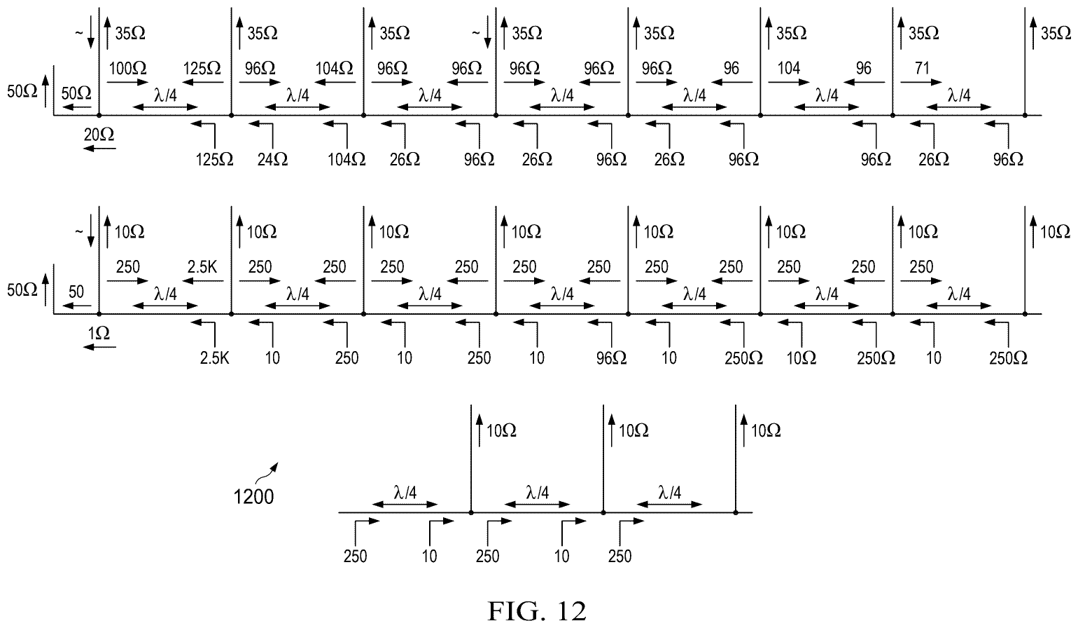

FIG. 12 illustrates an example use 1200 of the equivalent circuit 800 of FIG. 8 to model impedance in the asymmetric transmission line power combiner 105D of FIG. 6.

The following table compares the characteristics of the asymmetric transmission line power combiner 105D of FIG. 6 relative to the symmetric transmission line power combiner 105B of FIG. 3.

TABLE

| | Symmetric combiner | | Asymmetric combiner | |
|---|---|---|---|---|
| Parameter | 105B | | 105D | |
| Loss | 29-32 | dB | 18-23 | dB |
| Area | 0.64 | mm² | 0.16 | mm² |

| | | |
|---|---|---|
| Extra amplifiers | 2-3 | 1-2 |

Although the example transmission line power combiner 105D has been described in the context of a device including eight (8) transmitters, the transmission line power combiner 105D is not limited thereto. On the contrary, the transmission line power combiner 105D can be used in a device including fewer or more transmitters, such as 4 transmitters, 12 transmitters, 16 transmitters, etc.

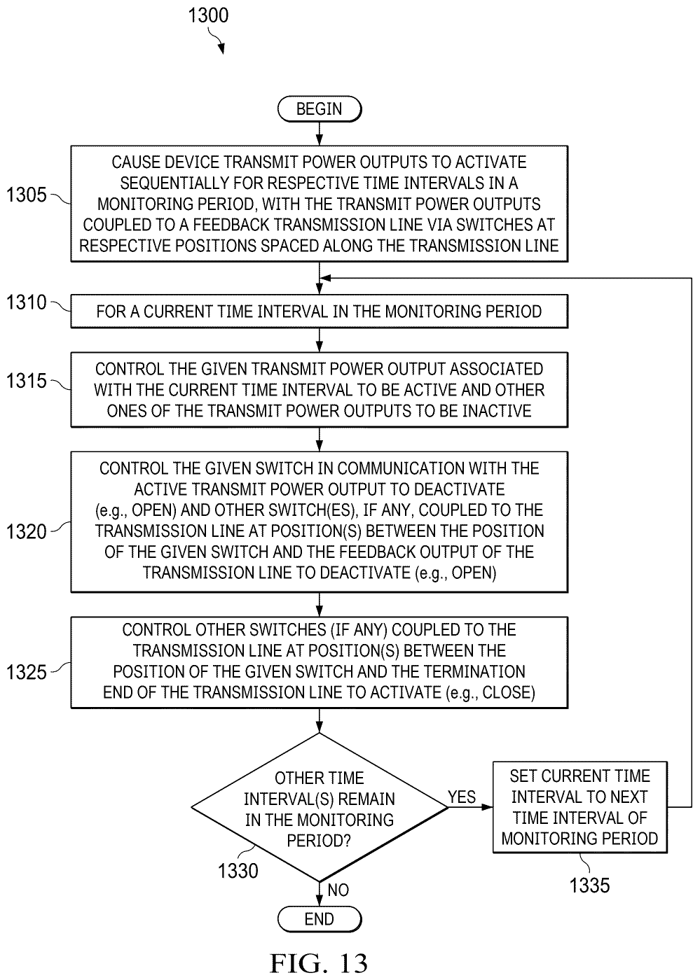

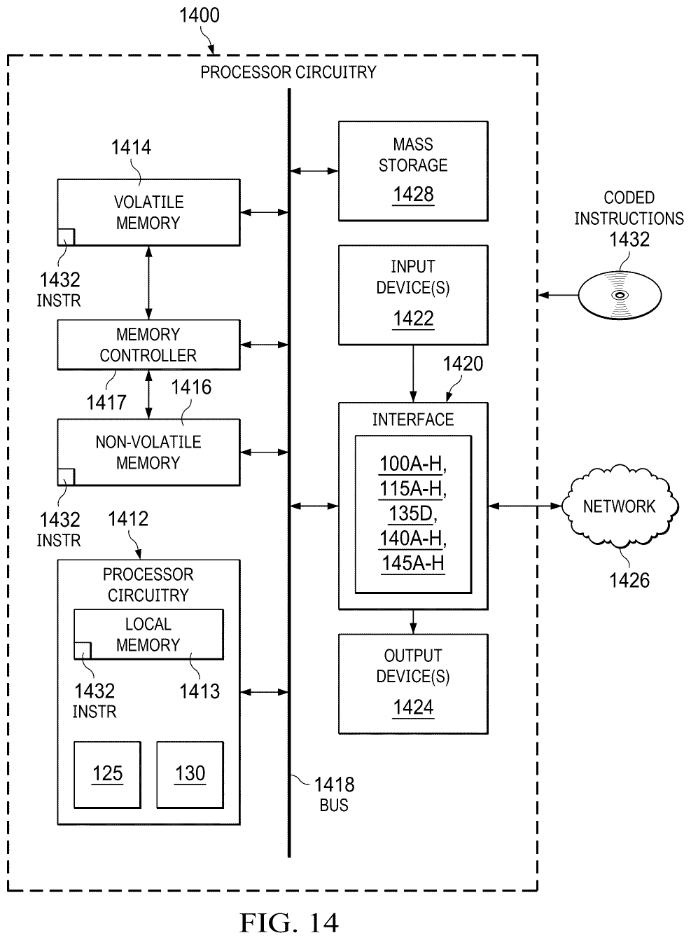

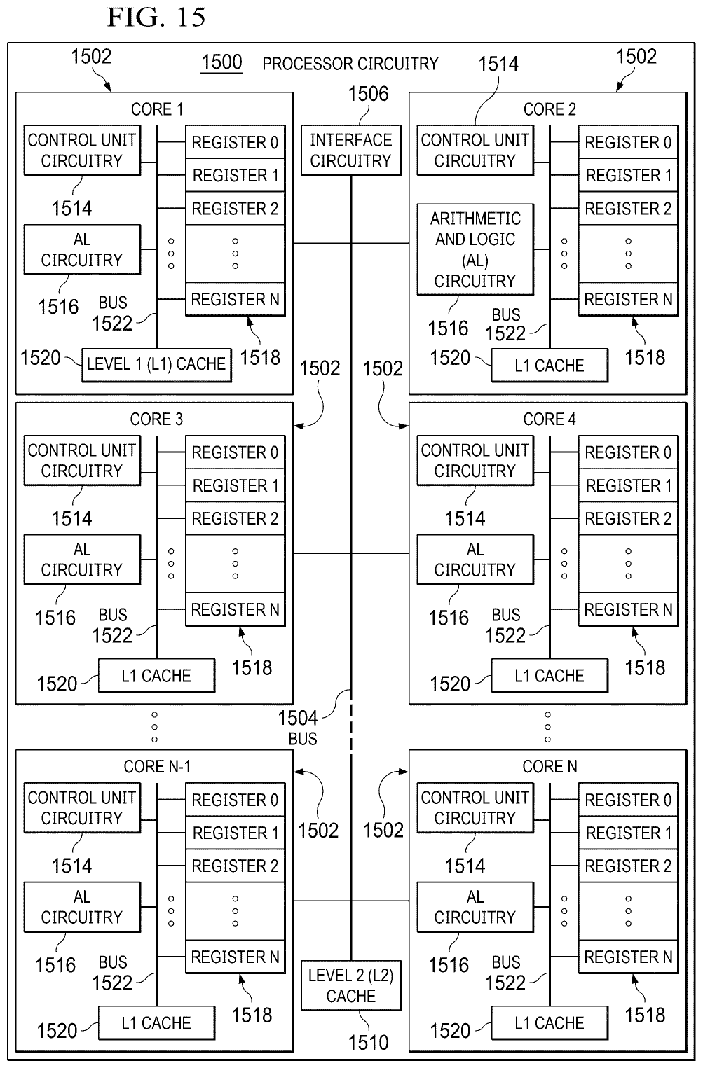

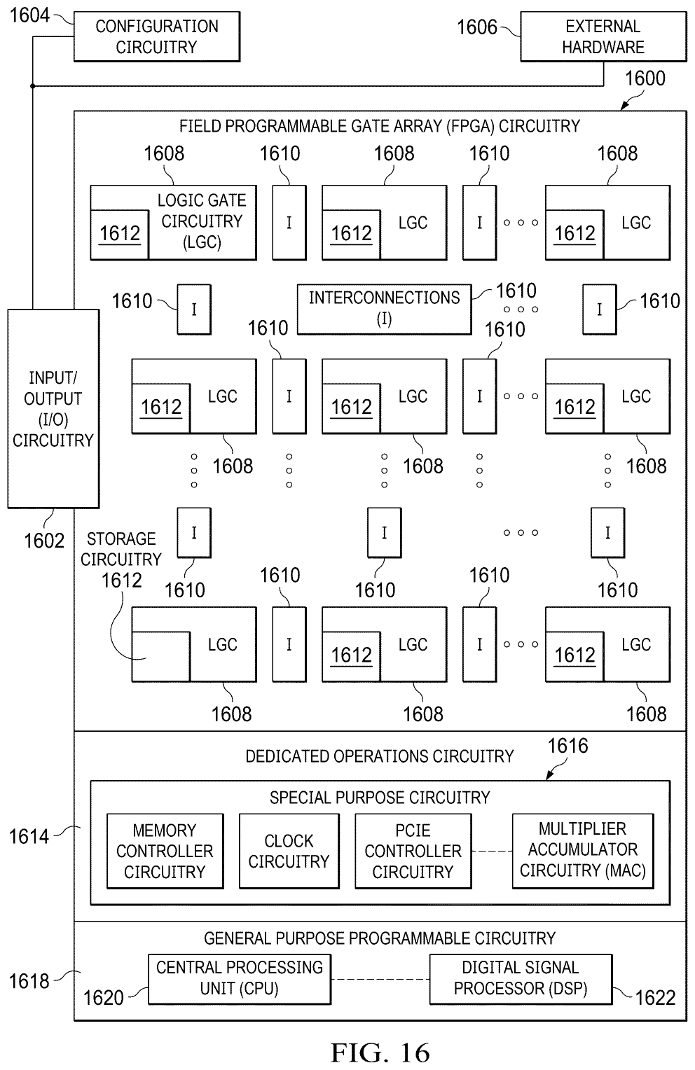

In some examples, the device 100 includes means for controlling power outputs and switches. For example, the means for controlling may be implemented by control circuitry 130. In some examples, the control circuitry 130 may be instantiated by programmable circuitry such as the example programmable circuitry 1412 of FIG. 14. For instance, the control circuitry 130 may be instantiated by the example microprocessor 1500 of FIG. 15 executing machine executable instructions such as those implemented by at least blocks 1305-1335 of FIG. 13. In some examples, the control circuitry 130 may be instantiated by hardware logic circuitry, which may be implemented by an ASIC, XPU, or the FPGA circuitry 1600 of FIG. 16 that are structured to perform operations corresponding to the machine-readable instructions. Also or alternatively, the control circuitry 130 may be instantiated by any other combination of hardware, software, or firmware. For example, the control circuitry 130 may be implemented by at least one or more hardware circuits (e.g., processor circuitry, discrete or integrated analog or digital circuitry, an FPGA, an ASIC, an XPU, a comparator, an operational-amplifier (op-amp), a logic circuit, etc.) configured or structured to execute some or all of the machine-readable instructions or to perform some or all of the operations corresponding to the machine-readable instructions without executing software or firmware, but other structures are likewise appropriate.

FIG. 13 is a flowchart representative of example machine-readable instructions and/or example operations 300 that may be at least one of executed, instantiated, or performed by programmable circuitry to implement the control circuitry 130 included in an implementation of the device 100 of FIG. 1 having the asymmetric transmission line power combiner 105D of FIG. 6. The example machine-readable instructions and/or the example operations 1300 of FIG. 13 begin at block 1305, at which the control circuitry 130 causes the device transmit power outputs 120A-H to activate sequentially for respective time intervals in a monitoring period, as described above. As also describe above, the transmit power outputs 120A-H are coupled to the feedback transmission line 135D via the switches 145A-H at respective positions 605-640 spaced along the transmission line 135D.

At block 1310, the control circuitry 130 cycles through the time intervals of a monitoring period, as described above. For example, at block 1315, the control circuitry 130 controls or otherwise causes a given transmit power output 120A-H associated with the current time interval to be active and other ones of the transmit power outputs 120A-H to be inactive, as described above. At block 1320, the control circuitry 130 controls or otherwise causes the given switch 145A-H in communication with the active transmit power output 120A-H to deactivate (e.g., open) and other switch(es) 145A-H, if any, coupled to the transmission line 135D at position(s) between the position 605-640 of the given switch 145A-H associated with the active transmit power output 120A-H and the output end 155D of the transmission line 135D to deactivate (e.g., open). At block 1325, the control circuitry 130 controls or otherwise causes other switches 145A-H (if any) coupled to the transmission line 135D at position(s) 605-640 between the position of the given switch 145A-H associated with the active transmit power output 120A-H and the termination end of the transmission line to activate (e.g., close).

At block 1330, the control circuitry 130 determines whether any time intervals remain in the current monitoring period. If any time intervals remain (corresponding to the “Yes” output of block 1330), at block 1335 the control circuitry 130 sets the next time interval of the monitoring period to be the current time interval. Processing then returns to block 1310 and blocks subsequent thereto at which the control circuitry 130 controls the power outputs 120A-H and switches 145A-H for the next time interval of the monitoring period, as described above. However, if no time intervals remain (corresponding to the “No” output of block 1330), then the example machine-readable instructions and/or the example operations 1300 of FIG. 13 end.

FIG. 14 is a block diagram of an example programmable circuitry platform 1400 structured to one or a combination of execute or instantiate one or more of the example machine-readable instructions or the example operations of FIG. 13 to implement the device 100 of FIGS. 1 and 6. The programmable circuitry platform 1400 can be, for example, an ADAS, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAs, microprocessors, CPUs, GPUs, DSPs, or microcontrollers from any desired family or manufacturer. The programmable circuitry 1412 may be implemented by one or more semiconductor based (e.g., silicon based) devices. In this example, the programmable circuitry 1412 implements the monitor circuitry 125 and the control circuitry 130.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1416 may be implemented by one or a combination of flash memory or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface. In the illustrated example, the interface circuitry implements the antennas 110A-H, PAs 115A-H, transmission line 135D, pads 140A-H, and switches 145A-H.

In the illustrated example, one or more input devices 1422 are connected to the interface circuitry 1420. The input device(s) 1422 permit(s) a user (e.g., a human user, a machine user, etc.) to enter one of or a combination of data or commands into the programmable circuitry 1412. The input device(s) 1422 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1424 are also connected to the interface circuitry 1420 of the illustrated example. The output device(s) 1424 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1420 of the illustrated example, thus, includes one of or a combination of a graphics driver card, a graphics driver chip, or graphics processor circuitry such as a GPU.

The interface circuitry 1420 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1400 of the illustrated example also includes one or more mass storage discs or devices 1428 to store one or more of firmware, software, or data. Examples of such mass storage discs or devices 1428 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1432, which may be implemented by the machine-readable instructions of FIG. 13, may be stored in one of or a combination of the mass storage device 1428, in the volatile memory 1414, in the non-volatile memory 1416, or on at least one non-transitory computer-readable storage medium such as a CD or DVD which may be removable.

FIG. 15 is a block diagram of an example implementation of the programmable circuitry 1412 of FIG. 14. In this example, the programmable circuitry 1412 of FIG. 14 is implemented by a microprocessor 1500. For example, the microprocessor 1500 may be a general-purpose microprocessor (e.g., general-purpose microprocessor circuitry). The microprocessor 1500 executes some or all of the machine-readable instructions of the flowchart of FIG. 13 to effectively instantiate the control circuitry 130 of FIG. 1 as logic circuits to perform operations corresponding to those machine-readable instructions. In some such examples, the control circuitry 130 of FIG. 1 is instantiated by the hardware circuits of the microprocessor 1500 in combination with the machine-readable instructions. For example, the microprocessor 1500 may be implemented by multi-core hardware circuitry such as a CPU, a DSP, a GPU, an XPU, etc. Although it may include any number of example cores 1502 (e.g., 1 core), the microprocessor 1500 of this example is a multi-core semiconductor device including N cores. The cores 1502 of the microprocessor 1500 may operate independently or may cooperate to execute machine-readable instructions. For example, machine code corresponding to a firmware program, an embedded software program, or a software program may be executed by one of the cores 1502 or may be executed by multiple ones of the cores 1502 at the same or different times. In some examples, the machine code corresponding to the firmware program, the embedded software program, or the software program is split into threads and executed in parallel by two or more of the cores 1502. The software program may correspond to a portion or all of the machine-readable instructions or operations represented by the flowchart of FIG. 13.

The cores 1502 may communicate by a first example bus 1504. In some examples, the first bus 1504 may be implemented by a communication bus to effectuate communication associated with one(s) of the cores 1502. For example, the first bus 1504 may be implemented by at least one of an Inter-Integrated Circuit (I2C) bus, a Serial Peripheral Interface (SPI) bus, a PCI bus, or a PCIe bus. Also or alternatively, the first bus 1504 may be implemented by any other type of computing or electrical bus. The cores 1502 may obtain data, instructions, and signals from one or more external devices by example interface circuitry 1506. The cores 1502 may output data, instructions, and signals to the one or more external devices by the interface circuitry 1506. Although the cores 1502 of this example include example local memory 1520 (e.g., Level 1 (L1) cache that may be split into an L1 data cache and an L1 instruction cache), the microprocessor 1500 also includes example shared memory 1510 that may be shared by the cores (e.g., Level 2 (L2 cache)) for high-speed access to data and instructions. Data and instructions may be transferred (e.g., shared) by one of or a combination of writing to or reading from the shared memory 1510. The local memory 1520 of each of the cores 1502 and the shared memory 1510 may be part of a hierarchy of storage devices including multiple levels of cache memory and the main memory (e.g., the main memory 1414, 1416 of FIG. 14).

Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1502 may be referred to as a CPU, DSP, GPU, etc., or any other type of hardware circuitry. Each core 1502 includes control unit circuitry 1514, arithmetic and logic (AL) circuitry (sometimes referred to as an ALU) 1516, a plurality of registers 1518, the local memory 1520, and a second example bus 1522. Other structures may be present. For example, each core 1502 may include vector unit circuitry, single instruction multiple data (SIMD) unit circuitry, load/store unit (LSU) circuitry, branch/jump unit circuitry, floating-point unit (FPU) circuitry, etc. The control unit circuitry 1514 includes semiconductor-based circuits structured to control (e.g., coordinate) data movement within the corresponding core 1502. The AL circuitry 1516 includes semiconductor-based circuits structured to perform one or more mathematic or logic operations on the data within the corresponding core 1502. The AL circuitry 1516 of some examples performs integer-based operations. In other examples, the AL circuitry 1516 also performs floating-point operations. In yet other examples, the AL circuitry 1516 may include first AL circuitry that performs integer-based operations and second AL circuitry that performs floating-point operations. In some examples, the AL circuitry 1516 may be referred to as an Arithmetic Logic Unit (ALU).

The registers 1518 are semiconductor-based structures to store data and instructions such as results of one or more of the operations performed by the AL circuitry 1516 of the corresponding core 1502. For example, the registers 1518 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1518 may be arranged in a bank as shown in FIG. 15. Alternatively, the registers 1518 may be organized in any other arrangement, format, or structure, such as by being distributed throughout the core 1502 to shorten access time. The second bus 1522 may be implemented by at least one of an I2C bus, a SPI bus, a PCI bus, or a PCIe bus.

Each core 1502 or, more generally, the microprocessor 1500 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1500 is a semiconductor device fabricated to include many transistors interconnected to implement the structures described above in one or more integrated circuits (ICs) contained in one or more packages.

The microprocessor 1500 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those discussed herein. A GPU, DSP, or other programmable device can also be an accelerator. Accelerators may be on-board the microprocessor 1500, in the same chip package as the microprocessor 1500, or in one or more separate packages from the microprocessor 1500.

FIG. 16 is a block diagram of another example implementation of the programmable circuitry 1412 of FIG. 14. In this example, the programmable circuitry 1412 is implemented by FPGA circuitry 1600. For example, the FPGA circuitry 1600 may be implemented by an FPGA. The FPGA circuitry 1600 can be used, for example, to perform operations that could otherwise be performed by the example microprocessor 1500 of FIG. 15 executing corresponding machine-readable instructions. However, once configured, the FPGA circuitry 1600 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1500 of FIG. 15 described above (which is a general purpose device that may be programmed to execute some or all of the machine-readable instructions represented by the flowchart(s) of FIG. 13 but whose interconnections and logic circuitry are fixed once fabricated), the FPGA circuitry 1600 of the example of FIG. 16 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIG. 13. In particular, the FPGA circuitry 1600 may be thought of as an array of logic gates, interconnections, and switches. The switches can be programmed to change how the logic gates are interconnected by the interconnections, effectively forming one or more dedicated logic circuits (unless and until the FPGA circuitry 1600 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 13. As such, the FPGA circuitry 1600 may be at least one of configured or structured to effectively instantiate some or all of the operations/functions corresponding to the machine-readable instructions of the flowchart(s) of FIG. 13 as dedicated logic circuits to perform the operations/functions corresponding to those software instructions in a dedicated manner analogous to an ASIC. Therefore, the FPGA circuitry 1600 may perform the operations/functions corresponding to the some or all of the machine-readable instructions of FIG. 13 faster than the general-purpose microprocessor can execute the same.

In the example of FIG. 16, the FPGA circuitry 1600 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1600 of FIG. 16 may at least one of access or load the binary file to cause the FPGA circuitry 1600 of FIG. 16 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1600 of FIG. 16 to at least one of configure or structure the FPGA circuitry 1600 of FIG. 16, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1600 of FIG. 16 may at least one of access or load the binary file to cause the FPGA circuitry 1600 of FIG. 16 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1600 of FIG. 16 to at least one of configure or structure the FPGA circuitry 1600 of FIG. 16, or portion(s) thereof.

The FPGA circuitry 1600 of FIG. 16, includes example input/output (I/O) circuitry 1602 to at least one of obtain or output data to/from at least one of example configuration circuitry 1604 or external hardware 1606. For example, the configuration circuitry 1604 may be implemented by interface circuitry that may obtain a binary file, which may be implemented by one or more of a bit stream, data, or machine-readable instructions, to configure the FPGA circuitry 1600, or portion(s) thereof. In some such examples, the configuration circuitry 1604 may obtain the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1606 may be implemented by external hardware circuitry. For example, the external hardware 1606 may be implemented by the microprocessor 1500 of FIG. 15.

The FPGA circuitry 1600 also includes an array of example logic gate circuitry 1608, a plurality of example configurable interconnections 1610, and example storage circuitry 1612. The logic gate circuitry 1608 and the configurable interconnections 1610 are configurable to instantiate one or more operations/functions that may correspond to at least some of the machine-readable instructions of FIG. 13 and/or other desired operations. The logic gate circuitry 1608 shown in FIG. 16 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1608 to enable configuration of one of or a combination of the electrical structures or the logic gates to form circuits to perform desired operations/functions. The logic gate circuitry 1608 may include other electrical structures such as look-up tables (LUTs), registers (e.g., flip-flops or latches), multiplexers, etc.

The configurable interconnections 1610 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1608 to program desired logic circuits.

The storage circuitry 1612 of the illustrated example is structured to store result(s) of the one or more of the operations performed by corresponding logic gates. The storage circuitry 1612 may be implemented by registers or the like. In the illustrated example, the storage circuitry 1612 is distributed amongst the logic gate circuitry 1608 to facilitate access and increase execution speed.

The example FPGA circuitry 1600 of FIG. 16 also includes example dedicated operations circuitry 1614. In this example, the dedicated operations circuitry 1614 includes special purpose circuitry 1616 that may be invoked to implement commonly used functions to avoid the need to program those functions in the field. Examples of such special purpose circuitry 1616 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1600 may also include example general purpose programmable circuitry 1618 such as an example CPU 1620 or an example DSP 1622. Other general purpose programmable circuitry 1618 may also or alternatively be present such as a GPU, an XPU, etc., that can be programmed to perform other operations.

Although FIGS. 15 and 16 illustrate two example implementations of the programmable circuitry 1412 of FIG. 14, many other approaches are contemplated. For example, FPGA circuitry may include an on-board CPU, such as one or more of the example CPU 1620 of FIG. 15. Therefore, the programmable circuitry 1412 of FIG. 14 may also be implemented by combining at least the example microprocessor 1500 of FIG. 15 and the example FPGA circuitry 1600 of FIG. 16. In some such hybrid examples, one or more cores 1502 of FIG. 15 may execute a first portion of the machine-readable instructions represented by the flowchart(s) of FIG. 13 to perform first operation(s)/function(s), the FPGA circuitry 1600 of FIG. 16 may be at least one of configured or structured to perform second operation(s)/function(s) corresponding to a second portion of the machine-readable instructions represented by the flowchart(s) of FIG. 13, and/or an ASIC may be at least one of configured or structured to perform third operation(s)/function(s) corresponding to a third portion of the machine-readable instructions represented by the flowchart(s) of FIG. 13.

Some or all of the control circuitry 130 of FIG. 1 may, thus, be instantiated at the same or different times. For example, same and/or different portion(s) of the microprocessor 1500 of FIG. 15 may be programmed to execute portion(s) of machine-readable instructions at the same and/or different times. In some examples, same and/or different portion(s) of the FPGA circuitry 1600 of FIG. 16 may be at least one of configured or structured to perform operations/functions corresponding to portion(s) of machine-readable instructions at the same and/or different times.

In some examples, some or all of the control circuitry 130 of FIG. 1 may be instantiated, for example, in one or more threads executing concurrently and/or in series. For example, the microprocessor 1500 of FIG. 15 may execute machine-readable instructions in one or more threads executing concurrently and/or in series. In some examples, the FPGA circuitry 1600 of FIG. 16 may be at least one of configured or structured to carry out operations/functions concurrently and/or in series. Moreover, in some examples, some or all of the control circuitry 130 of FIG. 1 may be implemented within one or more virtual machines or containers executing on the microprocessor 1500 of FIG. 15.

In some examples, the programmable circuitry 1412 of FIG. 14 may be in one or more packages. For example, at least one of the microprocessor 1500 of FIG. 15 or the FPGA circuitry 1600 of FIG. 16 may be in one or more packages. In some examples, an XPU may be implemented by the programmable circuitry 1412 of FIG. 14, which may be in one or more packages. For example, the XPU may include a CPU (e.g., the microprocessor 1500 of FIG. 15, the CPU 1620 of FIG. 16, etc.) in one package, a DSP (e.g., the DSP 1622 of FIG. 16) in another package, a GPU in yet another package, and an FPGA (e.g., the FPGA circuitry 1600 of FIG. 16) in still yet another package.

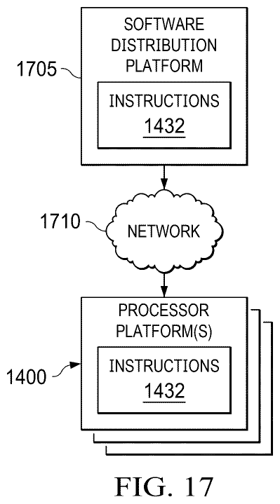

A block diagram illustrating an example software distribution platform 1705 to distribute software such as the example machine-readable instructions 1432 of FIG. 14 to other hardware devices (e.g., one or more hardware devices owned or operated by third parties from the owner or operator of the software distribution platform) is illustrated in FIG. 17. The example software distribution platform 1705 may be implemented by any computer server, data facility, cloud service, etc., capable of storing and transmitting software to other computing devices. The third parties may be customers of the entity at least one of owning or operating the software distribution platform 1705. For example, the entity that at least one of owns or operates the software distribution platform 1705 may be at least one of a developer, a seller, or a licensor of software such as the example machine-readable instructions 1432 of FIG. 14. The third parties may be consumers, users, retailers, OEMs, etc., who one of or a combination of purchase or license the software for at least one of use, re-sale, or sub-licensing. In the illustrated example, the software distribution platform 1705 includes one or more servers and one or more storage devices. The storage devices store the machine-readable instructions 1432, which may correspond to the example machine-readable instructions of FIG. 13, as described above. The one or more servers of the example software distribution platform 1705 are in communication with an example network 1710, which may correspond to any one or more of the Internet or any of the example networks described above. In some examples, the one or more servers are responsive to requests to transmit the software to a requesting party as part of a commercial transaction. Payment for at least one of the delivery, sale, or license of the software may be handled by the one or more servers of at least one of the software distribution platform or by a third-party payment entity. The servers enable one or more purchasers or licensors to download the machine-readable instructions 1432 from the software distribution platform 1705. For example, the software, which may correspond to the example machine-readable instructions of FIG. 13, may be downloaded to the example programmable circuitry platform 1400, which is to execute the machine-readable instructions 1432 to implement the control circuitry 130 of FIG. 1. In some examples, one or more servers of the software distribution platform 1705 periodically at least one of offer, transmit, or force updates to the software (e.g., the example machine-readable instructions 1432 of FIG. 14) to ensure improvements, patches, updates, etc., are distributed and applied to the software at the end user devices. Although referred to as software above, the distributed “software” could alternatively be firmware.

While an example manner of implementing the device 100 is illustrated in FIGS. 1 and 6, one or more of the elements, processes, or devices illustrated in FIGS. 1 and 6 may be combined, divided, re-arranged, omitted, eliminated, or implemented in any other way. Further, the monitor circuitry 125, the control circuitry 130, or, more generally, the example device 100 of FIGS. 1 and 6, may be implemented by hardware alone or by hardware in combination with software and firmware. Thus, for example, any of the monitor circuitry 125 or the control circuitry 130 could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example device 100 may include one or more elements, processes, or devices in addition to, or instead of, those illustrated in device 100 of FIGS. 1 and 6, or may include more than one of any or all of the illustrated elements, processes and devices.

Flowchart(s) representative of example machine-readable instructions, which may be executed by programmable circuitry to at least one of implement or instantiate the device 100 of FIGS. 1 and 6 or representative of example operations which may be performed by programmable circuitry to at least one of implement or instantiate device 100 of FIGS. 1 and 6, are shown in FIG. 13. The machine-readable instructions may be one or more executable programs or portion(s) of one or more executable programs for execution by programmable circuitry such as the programmable circuitry 1412 shown in the example processor platform 1400 discussed below in connection with FIG. 14 and may be one or more function(s) or portion(s) of functions to be performed by the example programmable circuitry (e.g., an FPGA) discussed below in connection with FIG. 15 or 16. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer-readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer-readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIG. 13, many other methods of implementing the example device 100 of FIGS. 1 and 6 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer-readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 13 may be implemented using executable instructions (e.g., computer-readable and/or machine-readable instructions) stored on one or more non-transitory computer-readable or machine-readable media. As used herein, the terms non-transitory computer-readable medium, non-transitory computer-readable storage medium, non-transitory machine-readable medium, and non-transitory machine-readable storage medium are expressly defined to include any type of computer-readable storage device or storage disk and to exclude propagating signals and to exclude transmission media. Examples of such non-transitory computer-readable medium, non-transitory computer-readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer-readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer-readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer-readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

From the foregoing, it will be appreciated that example systems, apparatus, articles of manufacture, and methods have been described that implement asymmetric transmission line power combiners. Described systems, apparatus, articles of manufacture, and methods improve the efficiency of a device, such as a radar device. For example, symmetric transmission line power combiners may be satisfactory for the loopback systems with two transmitters. But some modern radar devices include eight or sixteen transmitters in single die. Symmetric transmission line power combiners design to support that number of transmitters can consume substantial die area and exhibit high overall loss due to the overall length of the symmetric transmission line. In contrast, example asymmetric transmission line power combiners described herein work well with high number of transmitters, such as, eight or more, and are scalable to even higher numbers of transmitters, while reducing die area by at least a factor of four and overall loss by 7-9 dB relative to other symmetric transmission line power combiners. Properly sized switches can also lower the range of loss across the transmitter feedback paths of the asymmetric transmission line power combiner, such that the paths have similar loss parameters. As such, example asymmetric transmission line power combiners described herein can reduce the number of amplifiers required to boost the loopback signal and, thus, save 20-40 milliamperes (mA) of current consumption relative to other symmetric transmission line power combiners. Also, such a reduction in die area can lead to lower package sizes and overall costs. Furthermore, example asymmetric transmission line power combiners described herein are not limited to use in radar devices but can be used in any device having multiple transmitters having signals to be looped back or otherwise conveyed in the device via a transmission line. Thus, described systems, apparatus, articles of manufacture, and methods are also directed to one or more improvement(s) in the operation of a machine such as a computer or other electronic or electromechanical device.

Modifications are possible in the described embodiments, and other embodiments are possible, within the scope of the claims. Further examples and combinations thereof include the following. Example 1 includes a device comprising a first pad, a second pad, a transmission line including a first end configured to couple to monitor circuitry, wherein the transmission line includes a second end, a first switch coupled to the first pad, wherein the first switch is coupled to the transmission line between the first end and the second end, and a second switch coupled to the second pad and to the second end of the transmission line, wherein an impedance of the first switch is higher than an impedance of the second switch.

Example 2 includes the device of example 1, wherein the impedance of the first switch is at least twenty percent higher than the impedance of the second switch.

Example 3 includes the device of example 1 or example 2, wherein a channel width of the first switch is smaller than a channel width of the second switch.

Example 4 includes the device of any one of examples 1 to 3, wherein a distance between the first switch and the first end of the transmission line is less than a distance between the second switch and the first end of the transmission line.

Example 5 includes the device of any one of examples 1 to 4, comprising a first transmit power output coupled to the first pad, a second transmit power output coupled to the second pad, and control circuitry to cause the first switch to deactivate and the second switch to activate during a first time interval, the first transmit power output to be active during the first time interval, the second transmit power output to be inactive during the first time interval.

Example 6 includes the device of example 5, wherein the control circuitry is to cause the first switch to deactivate and the second switch to deactivate during a second time interval, the first transmit power output to be inactive during the second time interval, the second transmit power output to be active during the second time interval.

Example 7 includes the device of example 6, including a third pad, a third transmit power output coupled to the third pad, and a third switch coupled to the third pad, wherein the third switch is coupled to the transmission line between the first switch and the second switch, wherein the control circuitry is to cause the third switch to activate during the first time interval, the third transmit power output to be inactive during the first time interval, and cause the third switch to deactivate during the second time interval, the third transmit power output to be inactive during the second time interval.

Example 8 includes the device of example 7, wherein the control circuitry is to cause the first switch to deactivate, the second switch to activate and the third switch to deactivate during a third time interval, the first transmit power output to be inactive during the third time interval, the second transmit power output to be inactive during the third time interval and the third transmit power output to be active during the third time interval.

Example 9 includes the device of example 7, wherein an impedance of the third switch is lower than the impedance of the first switch and higher than the impedance of the second switch.

Example 10 includes the device of any one of examples 1 to 9, wherein the first switch and the second switch are shunt switches.

Example 11 includes a device comprising a transmission line having a first end and a second end, the first end to couple to circuitry to monitor a plurality of transmit power outputs of the device, and switches to couple the transmit power outputs with the transmission line, a first switch of the switches to couple a first transmit power output of the transmit power outputs to the transmission line between the first end and the second end of the transmission line, a second switch of the switches to couple a second transmit power output of the transmit power outputs to the second end of the transmission line, and the second switch having a lower impedance than the first switch.

Example 12 includes the device of example 11, wherein the circuitry is first circuitry, and comprising second circuitry to cause the first switch to deactivate and the second switch to activate during a first time interval, the first transmit power output to be active during the first time interval, the second transmit power output to be inactive during the first time interval.

Example 13 includes the device of example 12, wherein the second circuitry is to cause the first switch to deactivate and the second switch to deactivate during a second time interval, the first transmit power output to be inactive during the second time interval, the second transmit power output to be active during the second time interval.

Example 14 includes the device of example 13, wherein a third switch of the switches is to couple a third transmit power output of the transmit power outputs to the transmission line between the first switch and the second switch, and the second circuitry is to cause the third switch to activate during the first time interval, the third transmit power output to be inactive during the first time interval, and cause the third switch to deactivate during the second time interval, the third transmit power output to be inactive during the second time interval.

Example 15 includes the device of example 14, wherein the second circuitry is to cause the first switch to deactivate, the second switch to activate and the third switch to deactivate during a third time interval, the first transmit power output to be inactive during the third time interval, the second transmit power output to be inactive during the third time interval and the third transmit power output to be active during the third time interval.

Example 16 includes the device of example 14 or example 15, wherein the first switch has a first impedance, the second switch has a second impedance that is lower than the first impedance, and the third switch has a third impedance that is lower than the first impedance and higher than the second impedance.

Example 17 includes a non-transitory computer-readable medium comprising computer-readable instructions to cause at least one processor circuit to at least cause a plurality of transmit power outputs of a device to activate sequentially for respective time intervals in a monitoring period, the transmit power outputs in communication respectively with a plurality of switches coupled to a transmission line at respective positions spaced along the transmission line, the transmission line having a termination and an output, the output coupled to circuitry to monitor the transmit power outputs, and for a first one of the time intervals in which a first one of the transmit power outputs is active and other ones of the transmit power outputs are inactive cause a first one of the switches in communication with the first one of the transmit power outputs to deactivate, the first one of the switches coupled to the transmission line at a first one of the positions, and cause a second one of the switches coupled to the transmission line at a second one of the positions between the first one of the positions and the termination of the transmission line to activate.

Example 18 includes the non-transitory computer-readable medium of example 17, wherein the computer-readable instructions are to cause one or more of the at least one processor circuit to, for the first one of the time intervals, cause a third one of the switches coupled to the transmission line at a third one of the positions between the first one of the positions and the output of the transmission line to deactivate.

Example 19 includes the non-transitory computer-readable medium of example 17, wherein the computer-readable instructions are to cause one or more of the at least one processor circuit to, for the first one of the time intervals cause ones of the switches coupled to the transmission line between the first one of the positions and the termination of the transmission line to activate, and cause ones of the switches coupled to the transmission line between the first one of the positions and the output of the transmission line to deactivate.

Example 20 includes the non-transitory computer-readable medium of example 17, wherein the computer-readable instructions are to cause one or more of the at least one processor circuit to cause the switches to activate in time intervals outside the monitoring period.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

What is claimed is:

1. A device comprising:
a first pad;
a second pad;
a transmission line including a first end configured to couple to monitor circuitry, wherein the transmission line includes a second end;
a first switch coupled to the first pad, wherein the first switch is coupled to the transmission line between the first end and the second end; and
a second switch coupled to the second pad and to the second end of the transmission line,
wherein an impedance of the first switch is higher than an impedance of the second switch.

2. The device of claim 1, wherein the impedance of the first switch is at least twenty percent higher than the impedance of the second switch.

3. The device of claim 1, wherein a channel width of the first switch is smaller than a channel width of the second switch.

4. The device of claim 1, wherein a distance between the first switch and the first end of the transmission line is less than a distance between the second switch and the first end of the transmission line.

5. The device of claim 1, comprising:
a first transmit power output coupled to the first pad;
a second transmit power output coupled to the second pad; and
control circuitry to cause the first switch to deactivate and the second switch to activate during a first time interval, the first transmit power output to be active during the first time interval, the second transmit power output to be inactive during the first time interval.

6. The device of claim 5, wherein the control circuitry is to cause the first switch to deactivate and the second switch to deactivate during a second time interval, the first transmit power output to be inactive during the second time interval, the second transmit power output to be active during the second time interval.

7. The device of claim 6, including:
a third pad;
a third transmit power output coupled to the third pad; and
a third switch coupled to the third pad, wherein the third switch is coupled to the transmission line between the first switch and the second switch,
wherein the control circuitry is to:
cause the third switch to activate during the first time interval, the third transmit power output to be inactive during the first time interval; and
cause the third switch to deactivate during the second time interval, the third transmit power output to be inactive during the second time interval.

8. The device of claim 7, wherein the control circuitry is to cause the first switch to deactivate, the second switch to activate and the third switch to deactivate during a third time interval, the first transmit power output to be inactive during the third time interval, the second transmit power output to be inactive during the third time interval and the third transmit power output to be active during the third time interval.

9. The device of claim 7, wherein an impedance of the third switch is lower than the impedance of the first switch and higher than the impedance of the second switch.

10. The device of claim 1, wherein the first switch and the second switch are shunt switches.

11. A device comprising:
a transmission line having a first end and a second end, the first end to couple to circuitry to monitor a plurality of transmit power outputs of the device; and
switches to couple the transmit power outputs with the transmission line, a first switch of the switches to couple a first transmit power output of the transmit power outputs to the transmission line between the first end and the second end of the transmission line, a second switch of the switches to couple a second transmit power output of the transmit power outputs to the second end of the transmission line, and the second switch having a lower impedance than the first switch.

12. The device of claim 11, wherein the circuitry is first circuitry, and comprising second circuitry to cause the first switch to deactivate and the second switch to activate during a first time interval, the first transmit power output to be active during the first time interval, the second transmit power output to be inactive during the first time interval.

13. The device of claim 12, wherein the second circuitry is to cause the first switch to deactivate and the second switch to deactivate during a second time interval, the first transmit power output to be inactive during the second time interval, the second transmit power output to be active during the second time interval.

14. The device of claim 13, wherein a third switch of the switches is to couple a third transmit power output of the transmit power outputs to the transmission line between the first switch and the second switch, and the second circuitry is to:
cause the third switch to activate during the first time interval, the third transmit power output to be inactive during the first time interval; and
cause the third switch to deactivate during the second time interval, the third transmit power output to be inactive during the second time interval.

15. The device of claim 14, wherein the second circuitry is to cause the first switch to deactivate, the second switch to activate and the third switch to deactivate during a third time interval, the first transmit power output to be inactive during the third time interval, the second transmit power output to be inactive during the third time interval and the third transmit power output to be active during the third time interval.

16. The device of claim 14, wherein the first switch has a first impedance, the second switch has a second impedance that is lower than the first impedance, and the third switch has a third impedance that is lower than the first impedance and higher than the second impedance.

17. A non-transitory computer-readable medium comprising computer-readable instructions to cause at least one processor circuit to at least:
cause a plurality of transmit power outputs of a device to activate sequentially for respective time intervals in a monitoring period, the transmit power outputs in communication respectively with a plurality of switches coupled to a transmission line at respective positions spaced along the transmission line, the transmission line having a termination and an output, the output coupled to circuitry to monitor the transmit power outputs; and
for a first one of the time intervals in which a first one of the transmit power outputs is active and other ones of the transmit power outputs are inactive:
cause a first one of the switches in communication with the first one of the transmit power outputs to deactivate, the first one of the switches coupled to the transmission line at a first one of the positions; and
cause a second one of the switches coupled to the transmission line at a second one of the positions between the first one of the positions and the termination of the transmission line to activate.

18. The non-transitory computer-readable medium of claim 17, wherein the computer-readable instructions are to cause one or more of the at least one processor circuit to, for the first one of the time intervals, cause a third one of the switches coupled to the transmission line at a third one of the positions between the first one of the positions and the output of the transmission line to deactivate.

19. The non-transitory computer-readable medium of claim 17, wherein the computer-readable instructions are to cause one or more of the at least one processor circuit to, for the first one of the time intervals:
cause ones of the switches coupled to the transmission line between the first one of the positions and the termination of the transmission line to activate; and
cause ones of the switches coupled to the transmission line between the first one of the positions and the output of the transmission line to deactivate.

20. The non-transitory computer-readable medium of claim 17, wherein the computer-readable instructions are to cause one or more of the at least one processor circuit to cause the switches to activate in time intervals outside the monitoring period.
